(19) United States
(12) Patent Application Publication
(10) Pub. No.: US 2025/0233112 A1
(43) Pub. Date: Jul. 17, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: HsiaoYun Lo, Hsinchu City (TW); Tzu-Chiun Lin, New Taipei City (TW); Ken-Yu Chang, Hsinchu City (TW)

(73) Assignee: Taiwan Semiconductor Manufacturing Company, Ltd., Hsinchu (TW)

(21) Appl. No.: 18/413,062

(22) Filed: Jan. 16, 2024

(51) Int. Cl. H01L 25/065; H01L 23/00; H01L 23/498

(52) U.S. Cl. CPC H01L 25/0657; H01L 23/49827; H01L 24/05; H01L 24/08; H01L 24/89; H01L 24/94; H01L 2224/05006; H01L 2224/05147; H01L 2224/0807; H01L 2224/08145; H01L 2224/89; H01L 2224/94; H01L 2225/06524; H01L 2924/37001

(57) ABSTRACT

A stacking structure including a first die and a second die stacked the first die is provided. The first die includes a first substrate and a first bonding structure located over the first substrate. The second die includes a second substrate and a second bonding structure located over the second substrate. The first and second dies are bonded through the bonded first and second bonding structures. The bonded first and second bonding structures include fused bonding pads having homogeneous core pads and locking patterns surrounding the homogeneous core pads.

### BACKGROUND

Following advances in semiconductor manufacturing technologies, complex semiconductor structures incorporating different types of semiconductor dies are fabricated and integrated with integrated circuits (ICs) and electronic devices. It is important to establish reliable electrical inter-connection between the semiconductor dies and/or other devices to offer durable integration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic top view of an exemplary structure with multiple semiconductor die units in accordance with some embodiments of the present disclosure.

FIGS. 2-6 are schematic cross-sectional views showing various stages of the manufacturing method for forming a semiconductor stacking structure according to some embodiments of the present disclosure.

FIG. 7 through FIG. 9 are schematic enlarged cross-sectional views showing bonding structure(s) relative to the underneath element(s).

FIG. 10 is a diagram showing the bonding portion in accordance with some embodiments of the present disclosure.

FIGS. 11-14 are schematic cross-sectional views showing various stages of the manufacturing method for forming a semiconductor stacking structure according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

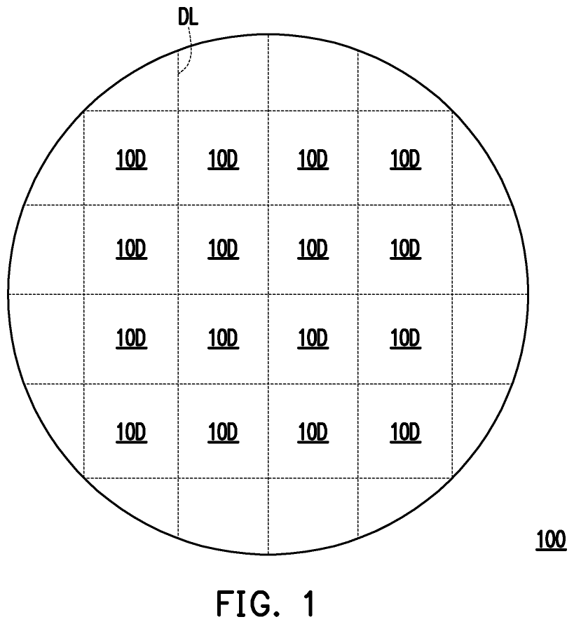

FIG. 1 is a schematic top view of an exemplary structure with multiple semiconductor die units in accordance with some embodiments of the present disclosure.

In FIG. 1, a wafer structure 100 is provided and may be used to form a semiconductor stacking structure or a package structure in packaging processes. In some embodiments, the wafer structure 100 has multiple dies units 10D defined or formed within. In some embodiments, the wafer structure 100 is a semiconductor bulk wafer with active devices and optional passive devices formed therein. In some embodiments, the wafer structures 100 may be a reconstructed wafer. As seen in FIG. 1, the dashed lines represent dicing lanes DL by which the wafer structure 100 will later be diced in a subsequent singulation process to obtain the dies 10D that are separated from each other through the singulation process. In some embodiments, the dies 10D are semiconductor dies having the same design and performing the same function. In some embodiments, the dies 10D include semiconductor dies having different designs and performing different functions.

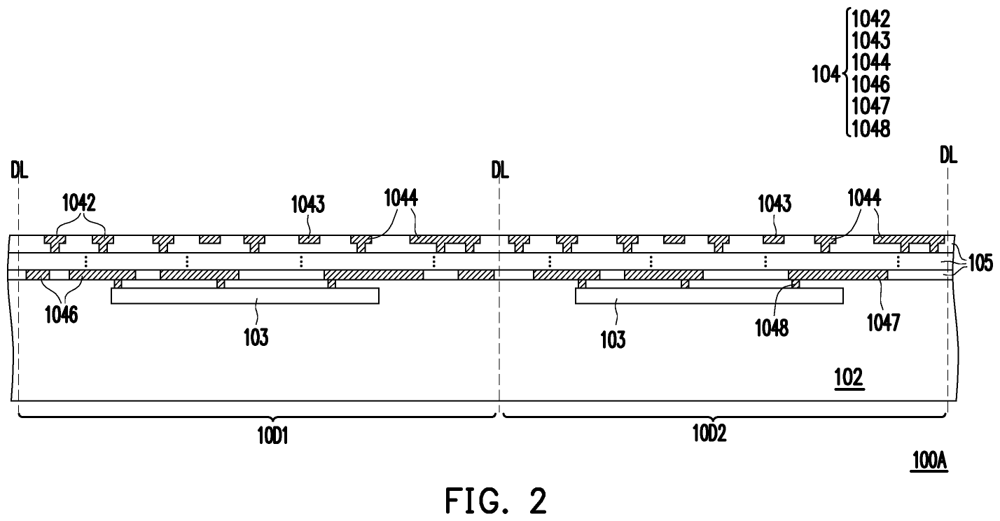

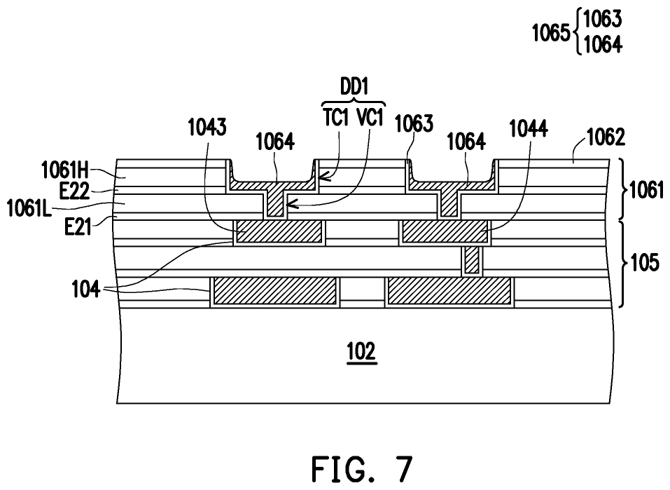

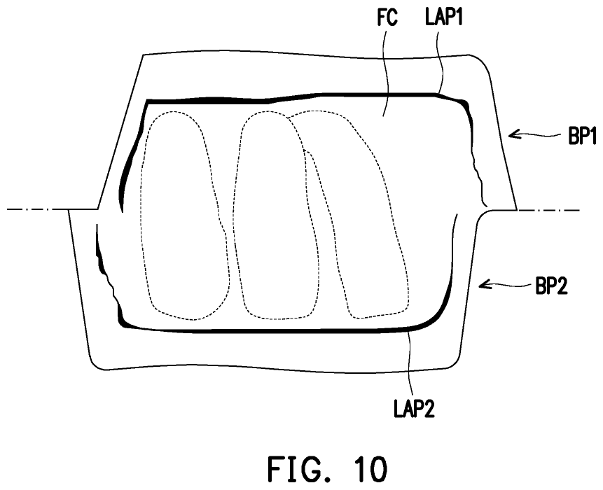

FIGS. 2-6 are schematic cross-sectional views showing various stages of the manufacturing method for forming a semiconductor stacking structure according to some embodiments of the present disclosure. The same components or elements of similar or the same structure configuration(s) may be labeled with the same reference labels in the drawings. FIG. 7 through FIG. 9 are schematic enlarged cross-sectional views showing bonding structure(s) relative to the underneath element(s). FIG. 10 is a diagram showing the bonding portion in accordance with some embodiments of the present disclosure.

In FIG. 2, in some embodiments, a wafer 100A is provided, and the wafer 100A is similar to the wafer structure 100 described in previous paragraph(s). In some embodiments, the wafer 100A is a semiconductor wafer, and the wafer 100A includes a semiconductor substrate 102 with a device layer 103, metallization structures 104 formed over the semiconductor substrate 102 and the device layer 103, and bonding structures 106 formed on the metallization structures 104 and over the semiconductor substrate 102. In some embodiments, the wafer 100A is a silicon wafer, or a bulk wafer made of other semiconductor materials such as III-V semiconductor materials such as gallium nitride (GaN) or gallium arsenide (GaAs). In some embodiments, the substrate 102 may be a monocrystalline semiconductor substrate such as a silicon substrate, a silicon-on-insulator (SOI) substrate, silicon-germanium on insulator (SGOI) or a germanium-on-insulator (GOI) substrate. In certain embodiments, the device layer 103 includes semiconductor devices formed in or on the semiconductor substrate 102 of the wafer 100 during the front-end-of-line (FEOL) processes. In certain embodiments, the semiconductor devices are active devices or include transistors, memories or power devices. In certain embodiments, the semiconductor devices are or include capacitors, resistors, diodes, photo-diodes, sensors, inductors or fuses. In exemplary embodiments, some of the semiconductor devices are electrically connected with the metallization structures 104, and some of the semiconductor devices are electrically inter-connected with one another through the metallization structures 104.

In some embodiments, the wafer 100A may be considered to have a plurality of die units or semiconductor dies before dicing or singulation. In FIG. 2, a portion of the wafer 100A including at least two die units 10D1 and 10D2 are shown and defined by the dicing lanes DL (in dotted lines). It is understood that the number of the die units or semiconductor dies is merely exemplary. In some embodiments, the die units (or semiconductor dies) 10D1 and 10D2 are or include different types of dies with different functions. In some embodiments, the die units (or semiconductor dies) 10D1 and 10D2 are or include the same type of dies or dies of the same functions.

As shown in FIG. 2, in certain embodiments, the metallization structures 104 are embedded within a dielectric material 105 formed on the semiconductor substrate 102. In some embodiments, the metallization structures 104 include multiple metallization layers of interconnect structures, including interconnected metal lines, vias and contact pads (certain detailed configurations and interlayers are omitted and represented by the ellipsis dots). In some embodiments, the metallization structures 104 at least include top metallization layer(s) 1042 and bottom metallization layer(s) 1046 that are electrically connected, and the bottom metallization layer 1046 is electrically connected to the device layer 103. In some embodiments, the top metallization layer(s) 1042 includes contacts 1043 and top metal lines 1044, and the bottom metallization layer(s) 1046 includes bottom metal lines 1047 and vias 1048 connected to the bottom metal lines 1047. The metallization structures 104 shown herein are merely for illustrative purposes, and the metallization structures 104 may include other configurations and may include one or more through vias and/or damascene structures. The disclosure does not limit the number of layers of the metallization layers and the number of sublayers included in the dielectric material 105, and the number of the layers or sublayers illustrated in the drawings is merely exemplary. Additional layers such as barrier layers, etch stop layers may also be formed in between the layers or sublayers thereof.

In certain embodiments, the materials of the metallization structures 104 include aluminum (Al), aluminum alloys, copper (Cu), copper alloys, titanium (Ti), tantalum (Ta), cobalt (Co), nickel (Ni), tungsten (W), nitrides thereof, or combinations thereof. In some embodiments, the contacts 1043 include aluminum pads, copper pads or copper alloy pads. In some embodiments, the top and bottom metallization layers 1042, 1046 (including metal lines 1044, 1047, the vias 1048) and metallic layers formed in-between are formed from the same metallization processes and are made of the same metal materials. In some embodiments, the top and bottom metallization layers 1042, 1046 (including metal lines 1044, 1047 and the vias 1048) are made of copper or copper alloys. In some embodiments, the dielectric material 105 includes silicon oxide, a spin-on dielectric material, a low-k dielectric material or a combination thereof. In some embodiments, the insulative dielectric material 105 includes one or more low-k dielectric layers. Examples include borophosporosilicate glass (BPSG), phosporosilicate glass (PSG), amorphous fluorinated carbon, parylene, BCB (bis-benzocyclobutenes), polyimide, flare, Xerogel, Aerogel, hydrogen silsesquioxane (HSQ), fluorinated silicon oxide (SiOF), or a combination thereof.

In exemplary embodiments, the semiconductor devices in the device layer 103 are electrically connected with the metallization structures 1046 through the bottom metal lines 1047 and the vias 1048. In some embodiments, the wafer 100A may include through semiconductor vias (TSVs) for further electrical connection. In some embodiments, the wafer 100A may include electrically unconnected seal ring structures embedded in the dielectric material 105 as structurally reinforcing elements.

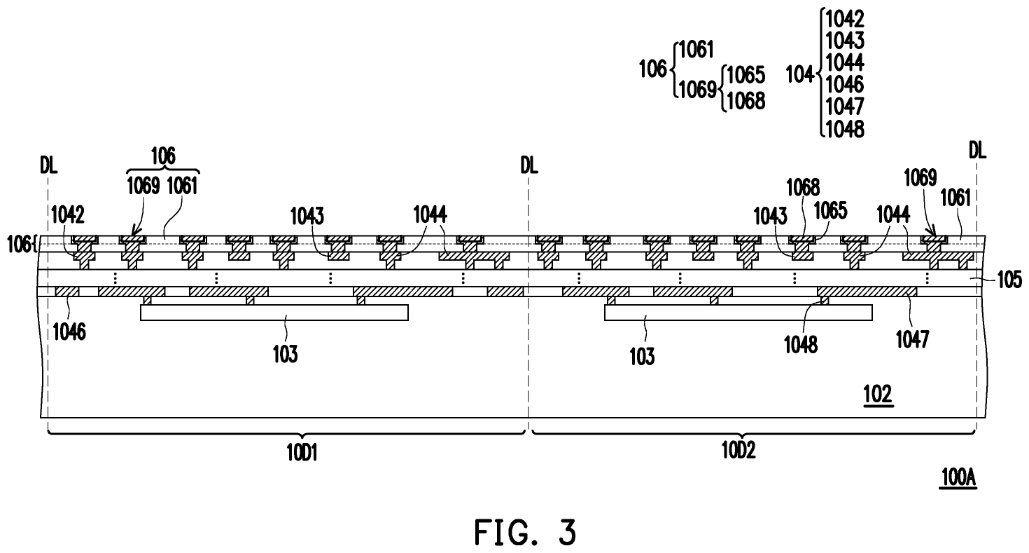

Referring to FIG. 3, in some embodiments, bonding structures 106 that include a dielectric material 1061 and bonding pads 1069 embedded in the dielectric material 1061 are formed over the dielectric material 105 and the metallization structures 104. In some embodiments, the metallization structures 104 electrically connect some of the semiconductor devices of the device layer 103 with the above bonding structures 106. The formation of the bonding structures 106 will be described in further details in the subsequent paragraphs.

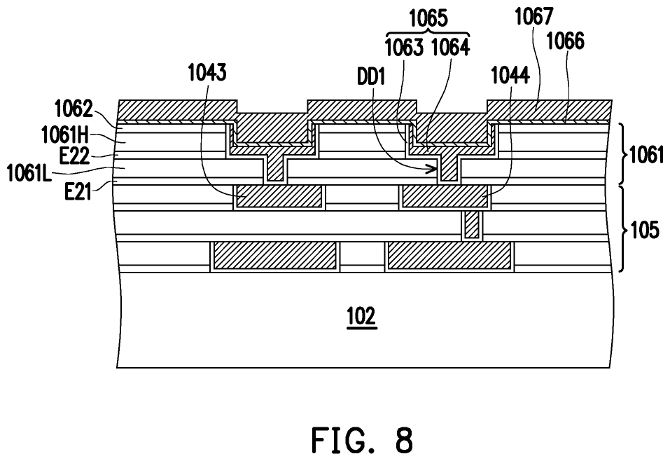

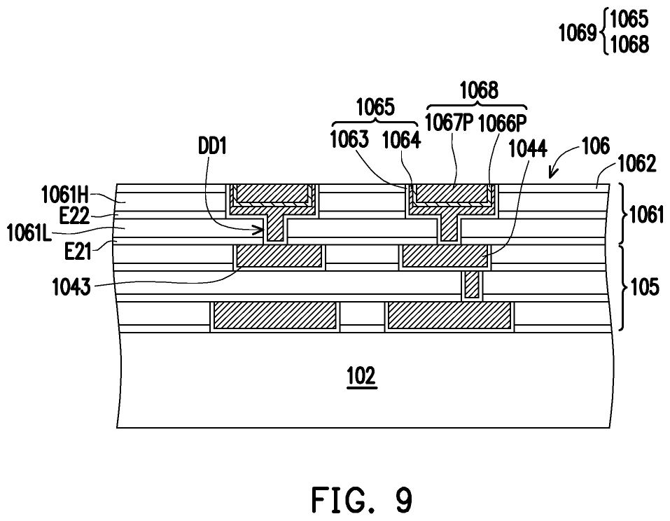

For illustration purposes, portions of the bonding structures 106 are illustrated in the schematic enlarged views of FIG. 7, FIG. 8 and FIG. 9 to show the exemplary configurations with more details. Referring to FIG. 7, in some embodiments, a dielectric material 1061 is formed on the dielectric material 105 covering the contact(s) 1043 and the top metal line(s) 1044 of the metallization structures 104 and over the substrate 102. Later, dual damascene openings DD1 are formed in the dielectric material 1061 through the dual damascene formation processes, and metallic base patterns 1065 are formed inside the dual damascene openings DD1.

In some embodiments, the formation of the dual damascene openings DD1 involves forming etch stop layer E21 and dielectric sublayer 1061L, etch stop layer E22 and dielectric sublayer 1061H and masking layer 1062 in sequence, patterning the masking layer 1062, through the patterned masking layer 1062, etching dielectric sublayer 1061H to form trench openings TC1 in dielectric sublayer 1061H (etching stopped at the etch stop layer E22), and etching dielectric sublayer 1061L to form via openings VC1 in dielectric sublayer 1061L (etching stopped at the etch stop layer E21). Hence, the trench opening(s) TC1 and the via opening(s) VC1 together form the dual damascene opening DD1, as seen in FIG. 7.

In some embodiments, the dielectric material 1061, including the dielectric sublayers 1061L, 1061B, include silicon oxide, silicon oxynitride (SiON), silicon carbonitride (SiCN) or oxide-based dielectric materials. In some embodiments, the individual dielectric sublayers such as 1061L, 1061H may be fabricated to a suitable thickness by flowable CVD (FCVD), CVD, HDPCVD, SACVD, spin-on, sputtering, or other suitable methods. In some embodiments, the material of the etch stop layers E21 and E22 includes silicon nitride or silicon carbide. In some embodiments, the material of the masking layer 1062 includes silicon nitride or silicon carbide.

In some embodiments, referring to FIG. 7, the formation of the metallic base pattern 1065 involves forming a barrier layer (not shown) over the dielectric material 1061 and conformally covering the dual damascene openings DD1, forming a metallic layer (not shown) over the barrier layer filling into the dual damascene openings DD1 (at least partially filling or filling up the dual damascene openings DD1, and partially removing (etching back process) the barrier layer outside the dual damascene openings DD1 to form a barrier pattern 1063 and partially removing the metallic layer to form metallic patterns 1064 inside the dual damascene openings DD1. In some embodiments, the etching back process removes the barrier layer and the metallic layer outside the dual damascene openings DD1 and partially removes the metallic layer without exposing the underlying barrier layer inside the dual damascene openings DD1 (the metallic layer still covering the barrier layer inside the dual damascene openings DD1).

Within the dual damascene openings DD1, the barrier pattern 1063 and the metallic pattern 1064 together form the metallic base pattern 1065. Referring to FIG. 7, as the barrier layer and the metallic layer outside the dual damascene openings DD1 or higher than the top surface of the masking layer 1062 are removed, the tops of the metallic pattern(s) 1064 and the barrier pattern(s) 1063 are levelled with or slightly lower than the top surface of the masking layer 1062. That is, the metallic base pattern(s) 1065 does not fill up the dual damascene opening(s) DD1, so that hollow space (or cavities) exists within the dual damascene openings DD1, as seen in FIG. 7.

In some embodiments, the material of the barrier layer or the barrier pattern 1063 includes titanium (Ti), tantalum (Ta), ruthenium (Ru), nitrides thereof or combinations thereof. In some embodiments, the barrier layer is formed with a thickness ranging from about 200 angstroms to about 1000 angstroms. In some embodiments, the barrier pattern 1063 includes a composite layer of titanium/titanium nitride (Ti/TiN), a composite layer of tantalum/tantalum nitride (Ta/TaN) or a Ru layer. In some embodiments, the material of the metallic pattern 1064 includes Cu or copper alloys. The formation of the metallic layer involves plating (such as electrochemical plating), deposition or other suitable process. It is understood that the dual damascene processing described herein is merely exemplary, and the opening(s) and the bonding structures formed within the openings may be formed through suitable formation process(es) for forming trenches, damascenes, via openings or other openings with suitable configurations.

Referring to FIG. 8, in some embodiments, following the formation of the metallic base patterns 1065, a locking auxiliary layer 1066 is formed over the patterned masking layer 1062 and conformally covers the exposed surfaces of the metallic base patterns 1065 without filling up the dual damascene openings DD1. Later, a metallic layer 1067 is formed on the locking auxiliary layer 1066 and over the patterned masking layer 1062 and fills up the dual damascene openings DD1.

In some embodiments, the locking auxiliary layer 1066 is formed as an oriented layer (a layer with a specific preferred crystalline orientation or a strong grain orientation) and functions as an orientating layer for the subsequently formed metallic layer 1067. With the existence of the locking auxiliary layer 1066, the later formed metallic layer 1067 is also an oriented layer with a similar preferred crystalline orientation (i.e. a similar grain orientation). In some embodiments, the material of the locking auxiliary layer 1066 includes Ti, Ta, silver (Ag), gold (Au), Ru or combinations thereof. In some embodiments, the locking auxiliary layer 1066 with a specific preferred crystalline orientation is formed by physical vapor deposition (PVD) with a thickness ranging from about 200 angstroms to about 1500 angstroms. In one embodiment, the locking auxiliary layer 1066 is or includes a titanium layer formed by PVD with a higher purity (less contamination). In one embodiment, the locking auxiliary layer 1066 is or includes a tantalum layer formed by PVD. In one embodiment, the locking auxiliary layer 1066 is formed with a thickness of about 250 angstroms to about 350 angstroms. Although the locking auxiliary layer 1066 is illustrated with a uniform thickness in the figures, it is possible that the thickness of the locking auxiliary layer 1066 varies depending on the underlying profiles. For example, the locking auxiliary layer 1066 may be formed to be thicker over the bottom portions of the opening(s) but thinner at the sidewalls of the opening(s). In some embodiments, the material of the metallic layer 1067 includes copper or copper alloys. For example, the metallic layer 1067 is formed by deposition (e.g., CVD, PVD, atomic layer deposition (ALD)), plating, or other suitable material-forming processes. In some embodiments, the material of the locking auxiliary layer 1066 is different from the material of the metallic layer 1067. In some embodiments, the material of the locking auxiliary layer 1066 is different from the material of the barrier layer.

Referring to FIG. 9, a planarization process is performing to the locking auxiliary layer 1066 and the metallic layer 1067 to remove the extra parts of the locking auxiliary layer 1066 and the metallic layer 1067 that are located outside the dual damascene openings DD1 and located on the patterned masking layer 1062 to form locking auxiliary patterns 1066P and metallic patterns 1067P. As seen in FIG. 9, the locking auxiliary pattern 1066P fully covers the sidewalls and the bottom surface of the metallic pattern 1067P. However, depending on whether the locking auxiliary layer is formed with a uniform thickness or not, it is possible that the locking auxiliary pattern 1066P partially covers the sidewalls and/or partially or fully covers the bottom surface of the metallic pattern 1067P. In some embodiments, the locking auxiliary pattern(s) 1066P and the metallic pattern(s) 1067P together form a main pad 1068. As seen in FIG. 9, the metallic base pattern(s) 1065 and the main pad(s) 1068 together form a bonding pad 1069 located in the individual opening DD1, and the bonding pads 1069 are embedded in the dielectric material 1061.

Referring to FIG. 9, the main pads 1068 are separated from the barrier patterns 1063 by the metallic patterns 1064. Also, the metallic patterns 1067P are separated from the metallic patterns 1064 by the locking auxiliary patterns 1066P. In some embodiments, as seen in FIG. 9, the locking auxiliary pattern(s) 1066P with a cross-sectional U shape (or a bowl shape) surrounds and encloses the metallic pattern(s) 1067P therein. In some embodiments, separated by the locking auxiliary pattern 1066P, the metallic pattern 1067P and the metallic pattern 1064 may be regarded as inner metallic pattern (e.g. pad shaped) and outer metallic pattern (e.g. ring shell-shaped).

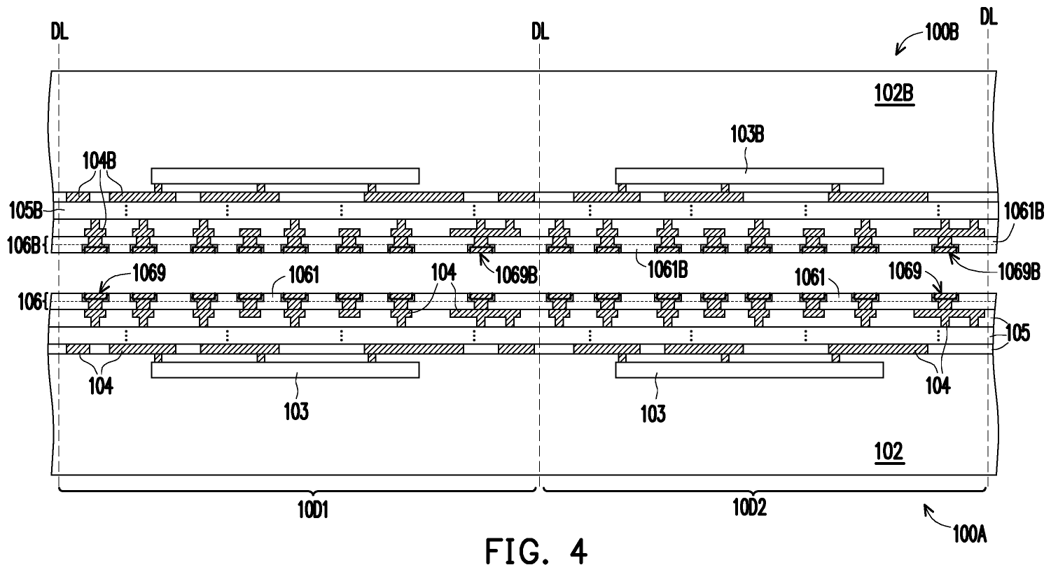

Referring to FIG. 4, another wafer 100B is provided, and the wafer 100B is similar to the wafer structure 100 or wafer 100A described in previous paragraph(s). In some embodiments, the wafer 100B is a semiconductor wafer, and the wafer 100B includes a semiconductor substrate 102B with a device layer 103B, metallization structures 104B formed over the semiconductor substrate 102B and the device layer 103B, and bonding structures 106B formed on the metallization structures 104B and over the semiconductor substrate 102B. Specifically, for the wafer 100B, the bonding structures 106B that include a dielectric material 1061B and bonding pads 1069B embedded in the dielectric material 1061B are substantially the same as the bonding structures 106 of the wafer 100A.

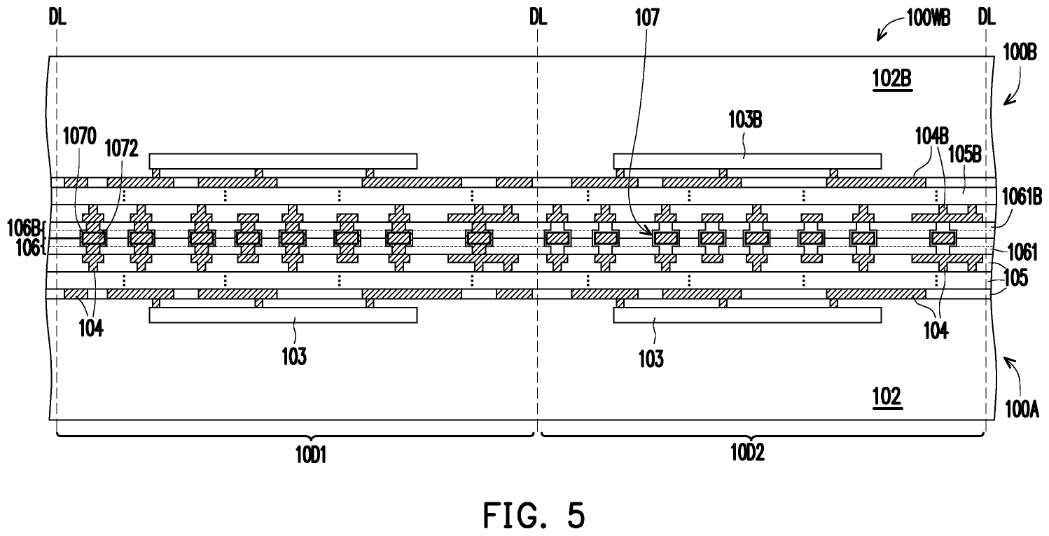

Later, referring to FIG. 4 and FIG. 5, after mounting and aligning the wafer 100B with the wafer 100A, a bonding process is performed to bond the wafers 100A and 100B through the bonding of the bonding structures 106 and 106B. In some embodiments, the bonding process is or includes a hybrid bonding process. In some embodiments, the bonding process involves performing a low temperature heating process performed under a temperature lower than about 300 degrees. With the existence of the locking auxiliary patterns 1066P inlaid in the bonding pads, the bonding process may be performed at a lower bonding temperature as the metallic patterns 1067 are formed with specific preferred crystalline orientation(s). In one embodiment, the bonding process is performed in two stages, a first temperature heating process at a temperature of about 100 degrees Celsius to about 200 degrees Celsius is performed to heat and bond the dielectric materials 1061, 1061B (dielectric-to-dielectric bonding) and a second temperature heating process is performed at a temperature of about 200 degrees Celsius to about 250 degrees Celsius to bond the bonding pads 1069, 1069B (metallic-to-metallic bonding). In one embodiments, the bonding process involves performing a low temperature heating process performed at a temperature of about 150 degrees Celsius to about 250 degrees Celsius, to heat and bond both the dielectric materials 1061, 1061B (dielectric-to-dielectric bonding) and the bonding pads 1069, 1069B (metallic-to-metallic bonding). In some embodiments, the wafers 100A and 100B are bonded through hybrid interfacial bonding to form a wafer-(stacked-) on-wafer structure 100WB.

Although the steps of the method are illustrated and described as a series of acts or events, it will be appreciated that the illustrated ordering of such acts or events are not to be interpreted in a limiting sense. In addition, further process or steps such as a singulation process may be performed to implement one or more embodiments of the present disclosure. The above illustrated processes belong to a wafer-on-wafer (WoW) process and may be further fabricated into 3D stacking packages or chip-on-wafer-on-substrate (CoWoS) packages.

Referring to FIG. 5, the wafers 100A and 100B are bonded through the dielectric-to-dielectric bonding of the dielectric materials 1061 and 1061B and the metal-to-metal bonding of the bonding pads 1069 and 1069B. After disposing the wafer 100B onto the wafer 100A, the bonding structures 106 and 106B, especially the corresponding bonding pads 1069 and 1069B, are aligned with each other, and during the low temperature heating process, the aligned bonding pads 1069 and 1069B are heated and bonded to form bonded bonding pads 107 having fused core pads 1072 without significant interfaces. In accordance with the embodiments of this disclosure, the fused core pads 1072 without significant interfaces (or voids or defects) may be described as homogeneous core pads for the bonded bonding pads 107.

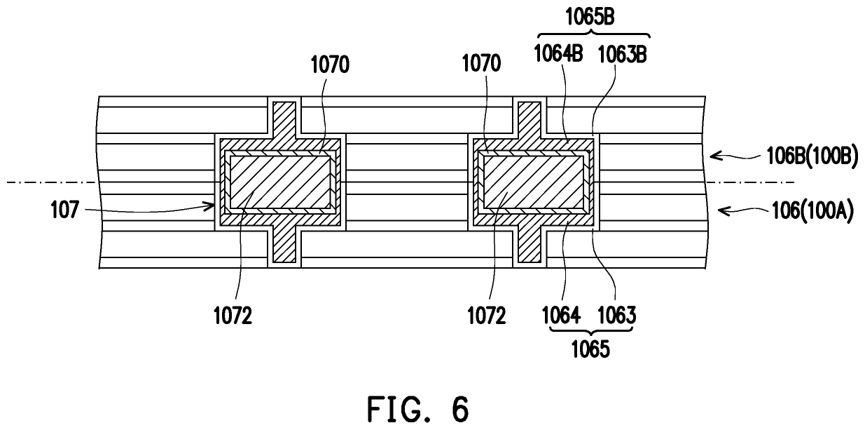

FIG. 6 is a schematic enlarged cross-sectional view showing the bonding portions of the bonding pads of the wafer-to-wafer bonded structure of FIG. 5 in accordance with some embodiments of the present disclosure. FIG. 10 is a diagram showing the bonding portion in accordance with some embodiments of the present disclosure. Referring to FIG. 6, after the bonding process, the aligned bonding pads 1069 and 1069B are bonded to become fused bonding pads 107. Referring to FIG. 6 with reference to FIG. 4-5 and FIG. 9, in some embodiments, through the heating of the bonding process, with the existence of the lock auxiliary patterns 1066P, the metallic materials of the metallic patterns 1067P from the respective bonding pads 1069, 1069B are merged, the metal atoms within the metallic patterns 1067P of the respective bonding pads 1069, 1069B are diffused, fused and merged into one integral core pad 1072 without significant interfaces. After the thermal process, the lock auxiliary patterns 1066P are mostly remained and become locking patterns 1070, and the metallic materials of the metallic patterns 1067P that are formed with specific grain orientations are fused and regrown with large grains over the touched interface (shown as dashed line) to form integral and homogeneous core pads 1072 with a diminished (or no) bonding interface, which leads to stronger bonding strength of the bonded bonding pads 107. Compared with conventional bonding pads without the locking auxiliary patterns, the bonding strength of the above described bonded bonding pads with fused core pads is increased by at least 20%˜30%.

In some embodiments, during the alignment of the respective bonding pads 1069, 1069B, it is preferred to precisely align the locking auxiliary patterns 1066P of the corresponding bonding pads. In some embodiments, with the precise alignment as shown in FIG. 6, it is seen that that the barrier patterns 1063 and 1063B are aligned, and the metallic patterns 1064, 1064B of the respective bonding pads 1069, 1069B are aligned and bonded with each other. In some embodiments, the bonded metallic base patterns 1065, 1065B of the respective bonding pads 1069, 1069B are aligned and bonded to form merged metallic shell. In some embodiments, the lock auxiliary patterns 1066P (FIG. 9) are aligned and bonded to form locking patterns 1070 for strengthening the bonding quality for the fused bonding pads 107. In some embodiments, with satisfactory alignment, the locking pattern 1070 may be formed into a cage-like shape or a box-like shape, and the fused core pad 1072 is a homogeneous metallic block mostly formed within the spans defined by the locking patterns 1070 (locking and confining within the locking pattern 1070), while the merged metallic shell is located outside and surrounds the locking pattern 1070.

Referring to FIG. 5 and FIG. 6, the wafer-to-wafer bonded structure 100WB includes the wafers 100A and 100B bonded through the bonded bonding pads 107 embedded in the fusion-bonded dielectric materials 1061 and 1061B. In some embodiments, the bonded bonding pads 107 include the fused core pads 1072 enclosed by the locking patterns 1070 (the remained auxiliary patterns 1066P).

As seen in FIG. 10, after the thermal process of the bonding process, the bonding pads BP1 and BP2 are bonded, and the locking auxiliary patterns LAP1 and LAP2 are remained within the bonding pads BP1 and BP2. From FIG. 10, it is seen that the spans of the bonding pads BP1 and BP2 are mostly overlapped but not completely overlapped (or not fully aligned). However, even though the alignment may not be perfect in FIG. 10, the metallic patterns of the main pads of the bonding pads BP1 and BP2 are bonded and fused into a fused core bonding portion FC with large grains (represented in dotted line) grown over the bonding interface (shown as the dashed line) and located within the span defined by the remained locking auxiliary patterns LAP1 and LAP2. Due to the formation of the oriented crystalline micro-structure (large grains), the fused core bonding portion FC is formed as an integral metallic block with large grains therein and no clear interface. It is seen that the fused core pad FC (fused core pad) is surrounded by the remained locking auxiliary patterns LAP1 and LAP2, and the remained locking auxiliary patterns LAP1 and LAP2 may not be connected. As a result, the bonded bonding pad having the fused core pad offers excellent bonding strength and reliability.

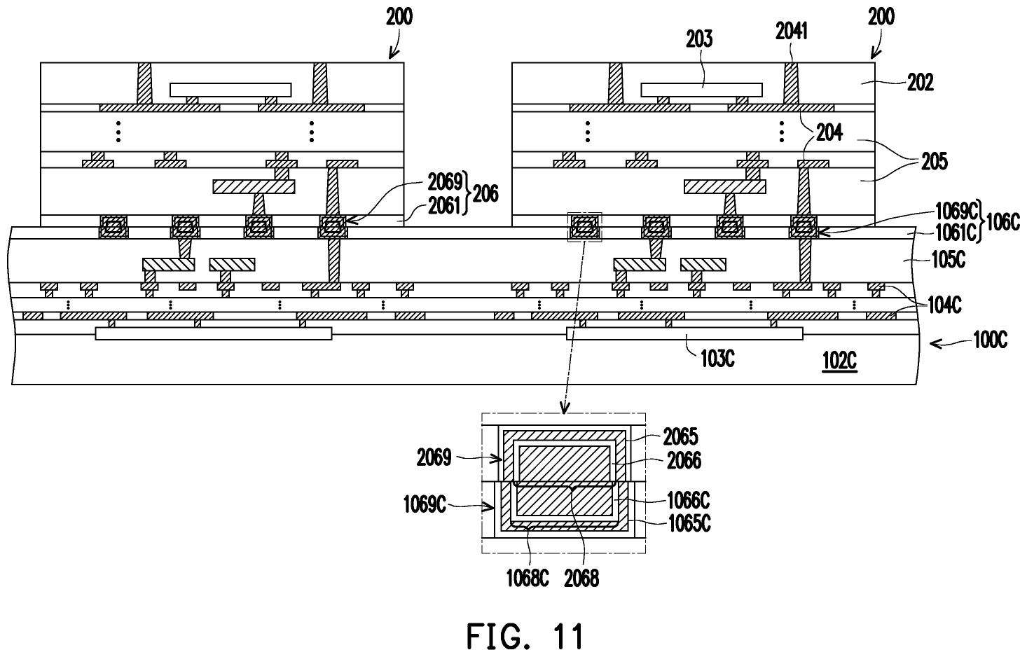

FIGS. 11-14 are schematic cross-sectional views showing various stages of the manufacturing method for forming a semiconductor stacking structure according to some embodiments of the present disclosure. Referring to FIG. 11, in some embodiments, a wafer 100C is provided, and the wafer 100C is similar to the wafer structure 100 and the wafer 100A as described in the previous paragraphs. In some embodiments, the wafer 100C is a semiconductor wafer, and the wafer 100C includes a semiconductor substrate 102C with a device layer 103C, metallization structures 104C formed over the semiconductor substrate 102C and the device layer 103C, and bonding structures 106C formed on the metallization structures 104C and over the semiconductor substrate 102C. Specifically, for the wafer 100C, the bonding structures 106C that include a dielectric material 1061C and bonding pads 1069C embedded in the dielectric material 1061C are substantially the same as the bonding structures 106 of the wafer 100A.

Referring to FIG. 11, multiple dies 200 (only two are shown) are provided and stacked onto the wafer 100C. For example, as seen in FIG. 11, multiple dies 200 are disposed side-by-side on the wafer 100C. In certain embodiments, each die 200 includes a semiconductor substrate 202, a device layer 203, metallization structures 204 embedded in the insulation material 205 formed on the semiconductor substrate 202 and bonding structures 206 formed on the second metallization structures 204 (from top to bottom as the second die 200 faces down). In embodiments, each die 200 includes semiconductor devices formed in the device layer 203 and isolation structures (not shown) formed in the semiconductor substrate 202. In certain embodiments, the metallization structures 204 include through semiconductor vias (TSVs) 2041 and interconnected metal lines and vias (certain detailed configurations and interlayers are omitted and represented by the ellipsis dots). In some embodiments, the bonding structure 206 includes a dielectric material 2061 and bonding pads 2069 in the dielectric material 2061. In some embodiments, as seen in the partially enlarged view in the lower part of FIG. 11, similar to the bonding pads 1069 of FIG. 3 and FIG. 9, the bonding pads 2069 include main pads 2068 and metallic base patterns 2065 surrounding and covering the main pads 2068, and the metallic base patterns 2065 and the main pads 2068 are separated by the locking auxiliary patterns 2066 sandwiched there-between. In some embodiments, some of the bonding pads 2069 are electrically connected with the metallization structures 204 and semiconductor devices in the device layer 203.

In some embodiments, among the dies 200, there are the same dies of the same function or the same size, or there are different dies performing different functions or of different sizes. In some embodiments, the dies 200 include logic dies, such as central processing unit (CPU) dies, graphic processing unit (GPU) dies, micro control unit (MCU) dies, baseband (BB) dies, or application processor (AP) dies, or memory dies, such as high bandwidth memory (HBM) dies, dynamic random access memory (DRAM) dies, or static random access memory (SRAM) dies. In some embodiments, the dies 200 include application-specific integrated circuit (ASIC) dies, analog dies, sensor dies, wireless application dies (including Bluetooth chips and/or radio frequency chips) or voltage regulator dies.

In some embodiments, the dies 200 are semiconductor dies fabricated from a semiconductor wafer with similar configuration design as shown for the die unit(s) of the wafer structure 100 or wafer 100A. In certain embodiments, the materials of the metallization structures 204 may be similar to or the same as that of the metallization structures 104. In certain embodiments, the materials of the dielectric material 2061 and the bonding pads 2069 of the bonding structures 206 may be similar to or the same as those of the bonding structures 106. During the placement of the dies 200, the dies 200 are arranged to align the bonding structures 206 with the corresponding bonding structures 106C of the wafer 100C respectively, so that the bonding pads 1069C and 2069 are substantially vertically aligned (along the stacking direction).

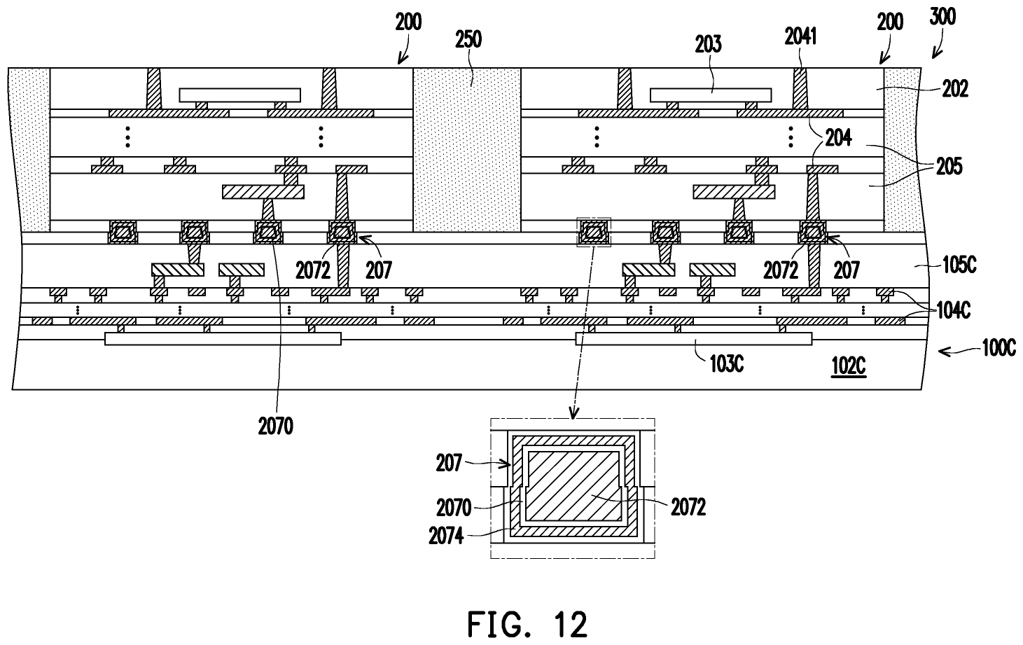

Then, in some embodiments, as shown in FIG. 12, a bonding process is performed to bond the bonding structures 106C and 206 so as to bond the dies 200 onto the wafer 100C. In some embodiments, the bonding process includes performing a low temperature heating process at a temperature of about 150 degrees Celsius to about 250 degrees Celsius to bond the dielectric materials 1061C, 2061 (dielectric-to-dielectric bonding) and the bonding pads 1069C, 2069 (metallic-to-metallic bonding). In some embodiments, the dies 200 are bonded to the wafer 100C through hybrid interfacial bonding to form a die-stacked-on-wafer structure.

Referring to FIG. 12, after stacking and bonding dies 200 onto the wafer 100C, a filling material 250 is formed over the die-stacked-on-wafer structure, especially filling the gaps between the dies 200 on the wafer 100C to form a molded structure 300. In some embodiments, the filling material 250 is an insulating material. In one embodiment, the filling material 250 is formed by chemical vapor deposition (CVD), spin coating or molding. In some embodiments, the material of the filling material 250 includes silicon oxide, silicon nitride, epoxy resins, phenolic resins or silicone resins. In some embodiments, the filling material 250 at least covers the top surface of the wafer 100C, fills the gaps between the dies 200 and covers the sidewalls of the dies 200. In some embodiments, the filling material 250 fully covers the dies 200 over the wafer 100C, and a planarization process is performed to partially remove the filling material 250 as well as portions of the dies 200. The planarization process includes performing a grinding process or a polishing process such as a chemical mechanical polishing process, for example. After planarization, the backsides of the dies 200 are polished and the TSVs 204 are exposed. In some embodiments, the planarized filling material 250 at least laterally covers the sidewalls of the dies 200 bonded onto the wafer 100C.

Referring to FIG. 12, after the bonding process, the aligned bonding pads 1069C and 2069 are heated and bonded to form bonding pads 207 having fused core pads 2072 without significant interfaces. In some embodiments, through the heating of the bonding process, with the existence of the lock auxiliary patterns 2066 and 1066C, the main pads 2068 and 1068C are fused and merged into one integral core pad(s) 2072 without significant interfaces. As seen in the enlarged view at the lower part of FIG. 12, for the bonded bonding pads 207, the metallic base patterns 2065 and 1065C are bonded to form merged metallic shell 2074, the remained locking auxiliary patterns 2066 and 1066C (see FIG. 11) become the locking patterns 2070, and the fused and homogeneous core pads 2072 are formed with a diminished (or no) bonding interface as large grains are grown over the previously contact interface, which leads to stronger bonding strength of the fused bonding pads 207. Through the formation of the fused bonding pads 207 with homogeneous core pads 2072, stronger and more reliable bonding is established between the dies 200 and the wafer 100C. It is understood that the area/size of the bonding pads 1069C of the wafer 100C may be larger than the area/size of the bonding pads 2069 of the die 200. It is also possible the spans of the main pads 1068C and 2068 may be different but matched (i.e. mostly overlapped but not exactly the same or fully overlapped).

By way of forming the locking auxiliary patterns inside the bonding pads of the bonding structures, high quality of bonding is established for the semiconductor structure fabricated from die-on-wafer processes or wafer-on-wafer processes. Also, stronger bonding is achieved between different types of die(s) of the semiconductor stacking structures such as multiple die stacked structures, system integrated chips or 3D integrated chiplets.

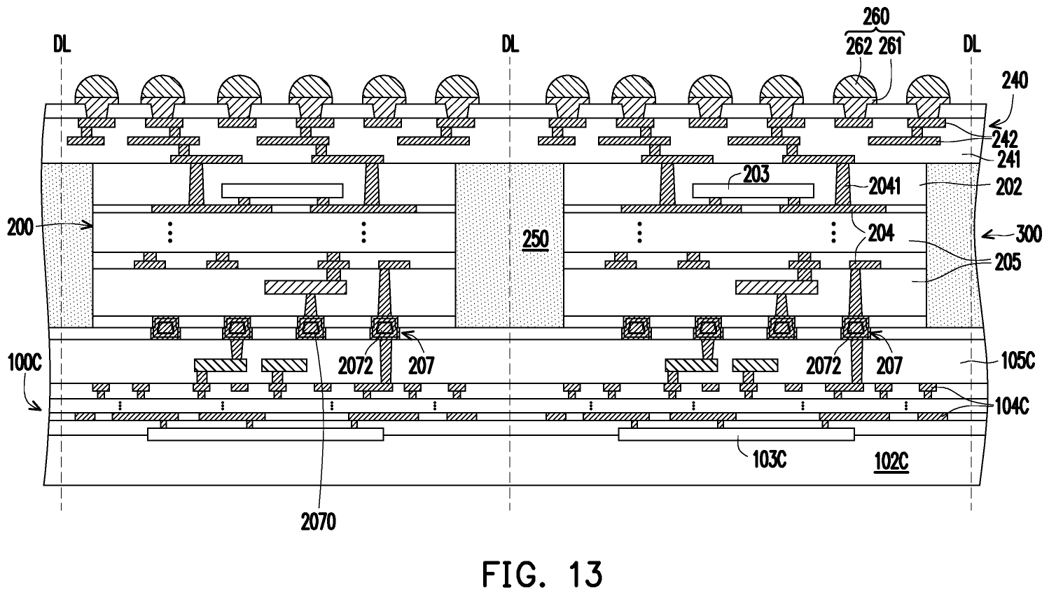

Referring to FIG. 13, in some embodiments, a redistribution layer (RDL) 240 is formed over the molded structure 300 and is formed on the filling material 250 and on the second dies 200. The redistribution layer (RDL) 240 is electrically connected to the dies 200 through at least the TSVs 2041. In some embodiments, the RDL 240 includes redistribution metal patterns 242 embedded in a dielectric material layer 241. The configuration of the redistribution metal patterns is not limited by the disclosure, while the dielectric material layer may include more than one layers of dielectric materials. The redistribution metal patterns 242 includes routing metal patterns, vias and metal pads, for example. In certain embodiments, the dielectric material layer 241 exposes some of the underlying redistribution metal patterns 242, and conductive terminals 260 are formed on the exposed metal patterns 242. In some embodiments, the conductive terminal 260 includes a metal post 261 and a bump 262. In some embodiments, the material of the dielectric material layer 241 includes silicon oxide, silicon nitride, low-k dielectric materials, benzocyclobutene (BCB), epoxy, polyimide (PI), or polybenzoxazole (PBO). In some embodiments, a material of the metal post 261 includes copper or cooper alloys, and a material of the bump 262 includes solder. In one embodiment, the metal posts 261 and bumps 262 located on the metal posts 261 constitute micro bumps. In some embodiments, the conductive terminals 260 include copper pillar bumps.

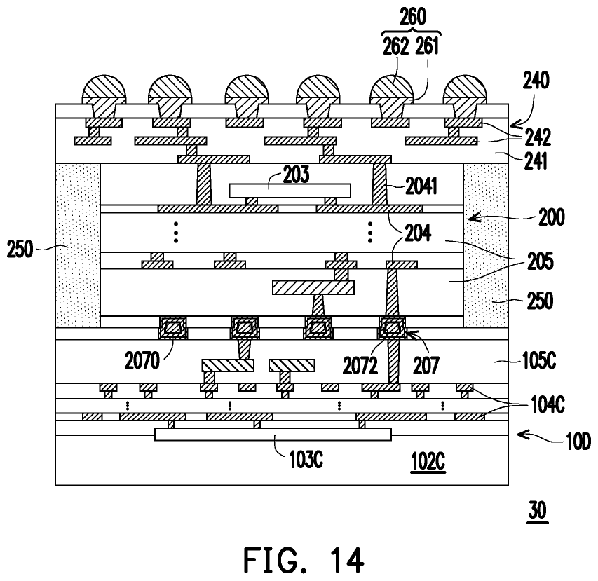

Later, in some embodiments, referring to FIG. 13 and FIG. 14, a singulation process is performed to cut the molded structure 300 and cutting through the RDL 240 along the dicing lanes DL into individual three-dimensional (3D) stacking structures 30. In exemplary embodiments, in reference to the exemplary arrangement having at least one second die 200 included within one die unit (defined by the dicing lanes DL) as shown in FIG. 13, after singulation, each of the singulated 3D stacking structures 30 includes at least one second die 200 stacked on the semiconductor die 10D and the filling material 250 wrapping around the second die 200. In some embodiments, the singulation process includes a wafer dicing process or a sawing process.

Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure. Furthermore, whilst the illustrated processes belong to a chip-on-wafer (CoW) process and may be further fabricated into 3D stacking packages or chip-on-wafer-on-substrate (CoWoS) packages.

In some embodiments, through the metallization structures 104C, 204 and the bonding structures 106C, 206, electrical connection paths are established between the semiconductor dies 10D, 200 of the 3D stacking structure 30. For the obtained 3D stacking structure 30, strong bonding is established between the dies 10D and 200 by way of the fused bonding pads 207 including the homogeneous core pads 2072 with no significant interfaces, and better reliability and satisfactory electrical performance are offered.

According to the embodiments of this disclosure, the formation of additional locking auxiliary patterns in the bonding pads enhances the bonding strength and reduces poor bonding due to voids occurred at bonding interfaces.

In some embodiments of the present disclosure, a stacking structure is provided. The stacking structure includes a first die and a second die stacked on the first die. The first die includes a first substrate and a first bonding structure located over the first substrate. The second die includes a second substrate and a second bonding structure located over the second substrate. The first and second dies are bonded through the bonded first and second bonding structures. The bonded first and second bonding structures include fused bonding pads having homogeneous core pads and locking patterns surrounding the homogeneous core pads.

In some embodiments of the present disclosure, a stacking structure is provided. The stacking structure includes a first die, and a second die stacked on and bonded with the first die. The first die has a first bonding structure including a first bonding pad embedded in a first dielectric material, and the first bonding pad includes a first auxiliary pattern and a first metallic material. The second die has a second bonding structure including a second bonding pad embedded in a second dielectric material, and the second bonding pad includes a second auxiliary pattern and a second metallic material. The first and second dies are bonded through the bonded first and second bonding structures with the bonded first and second bonding pads embedded in the bonded first and second dielectric materials. The bonded first and second bonding pads include the bonded first and second auxiliary patterns and a fused core pad that includes the first and second metallic materials and is surrounded by the bonded first and second auxiliary patterns.

In some embodiments of the present disclosure, a method for forming stacking structures is described. A first wafer having first dies is provided. Each first die has a first bonding structure including a first bonding pad embedded in a first dielectric material, and the first bonding pad includes a first inner metallic pattern, a first outer metallic pattern and a first auxiliary pattern sandwiched between the first inner and outer metallic pattern. Second dies are provided. Each second die has a second bonding structure including a second bonding pad embedded in a second dielectric material, and the second bonding pad includes a second inner metallic pattern, a second outer metallic pattern and a second auxiliary pattern sandwiched between the second inner and outer metallic patterns. The second bonding pads of the second dies are aligned with the first bonding pads of the first dies. The second dies are bonded with the first dies by bonding the first and second dielectric materials and bonding the first and second bonding pads of the first and second bonding structures. The first and second bonding pads are boned to form fused core pads by merging the first and second inner metallic patterns and the first and second auxiliary patterns are remained and located around the fused core pads. A singulation process is performed to form individual stacking structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A stacking structure, comprising:
a first die, wherein the first die includes a first substrate and a first bonding structure located over the first substrate; and
a second die stacked on the first die, wherein the second die includes a second substrate and a second bonding structure located over the second substrate,
wherein the first and second dies are bonded through the bonded first and second bonding structures, the bonded first and second bonding structures include fused bonding pads having homogeneous core pads and locking patterns surrounding the homogeneous core pads.

2. The structure of claim 1, wherein a material of the homogeneous core pads is different from a material of the locking patterns.

3. The structure of claim 2, wherein the fused bonding pads include metallic base patterns surrounding and covering the locking patterns.

4. The structure of claim 3, wherein the metallic base patterns include metallic patterns and barrier patterns surrounding and covering the metallic patterns.

5. The structure of claim 4, wherein a material of the metallic patterns is different from the material of the locking patterns.

6. The structure of claim 4, wherein a material of the barrier patterns is different from the material of the locking patterns.

7. The structure of claim 1, wherein the homogenous core pads are in direct contact with the locking patterns and are directly covered by the locking patterns.

8. The structure of claim 1, wherein the first bonding structure includes first metallization structures located over the first substrate, the second bonding structure includes second metallization structures over the second substrate, and the first and second dies are electrically connected through the fused bonding pads and the first and second metallization structures connected with the fused bonding pads.

9. The structure of claim 8, wherein the second metallization structures include through semiconductor vias, and the redistribution structure is electrically connected with the second die via the through semiconductor vias.

10. The structure of claim 1, further comprising a redistribution structure disposed on the second die.

11. A stacking structure, comprising:
a first die having a first bonding structure including a first bonding pad embedded in a first dielectric material, and the first bonding pad includes a first auxiliary pattern and a first metallic material; and
a second die stacked on and bonded with the first die, wherein the second die has a second bonding structure including a second bonding pad embedded in a second dielectric material, and the second bonding pad includes a second auxiliary pattern and a second metallic material,
wherein the first and second dies are bonded through the bonded first and second bonding structures with the bonded first and second bonding pads embedded in the bonded first and second dielectric materials, and the bonded first and second bonding pads include the bonded first and second auxiliary patterns and a fused core pad that includes the first and second metallic materials and is surrounded by the bonded first and second auxiliary patterns.

12. The structure of claim 11, further comprising a filling material disposed on the first die and around the second die.

13. The structure of claim 11, wherein the fused core pad includes a homogeneous metallic block with large grains therein.

14. The structure of claim 11, wherein a material of the fused core pad is different from a material of the first auxiliary pattern and a material of the second auxiliary pattern.

15. The structure of claim 14, wherein the bonded first and second bonding pads include a metallic shell surrounding the bonded first and second auxiliary patterns and the fused core pad.

16. A method for forming stacking structures, comprising:
providing a first wafer having first dies, each first die having a first bonding structure including a first bonding pad embedded in a first dielectric material, and the first bonding pad includes a first inner metallic pattern, a first outer metallic pattern and a first auxiliary pattern sandwiched between the first inner and outer metallic pattern;
providing second dies, wherein each second die has a second bonding structure including a second bonding pad embedded in a second dielectric material, and the second bonding pad includes a second inner metallic pattern, a second outer metallic pattern and a second auxiliary pattern sandwiched between the second inner and outer metallic patterns;
aligning the second bonding pads of the second dies with the first bonding pads of the first dies;
bonding the second dies with the first dies by bonding the first and second dielectric materials and bonding the first and second bonding pads of the first and second bonding structures, wherein the first and second bonding pads are boned to form fused core pads by merging the first and second inner metallic patterns and the first and second auxiliary patterns are remained and located around the fused core pads; and
performing a singulation process to form individual stacking structures.

17. The method of claim 16, further comprising forming a filling material over the first wafer and covering the second dies and filling up gaps between the second dies.

18. The method of claim 17, further comprising forming a redistribution layer on the second dies and the filling material, and forming conductive terminals on the redistribution layer.

19. The method of claim 16, wherein the second dies are included in a second wafer and are provided as the second wafer.

20. The method of claim 16, wherein aligning the second bonding pads of the second dies with the first bonding pads of the first dies includes aligning the second auxiliary patterns in the second bonding pads with the first auxiliary patterns in the first bonding pads.
